(19) United States
(12) Patent Application Publication
(10) Pub. No.: US 2002/0144642 A1
(43) Pub. Date: Oct. 10, 2002

(54) Apparatus and process for the preparation of low-iron single crystal silicon substantially free of agglomerated intrinsic point defects

(76) Inventors: Hariprasad Sreedharamurthy, Ballwin, MO (US); Mohsen Banan, Grover, MO (US); John D. Holder, Lake St. Louis, MO (US)

Correspondence Address: SENNIGER POWERS LEAVITT AND ROEDEL, ONE METROPOLITAN SQUARE, 16TH FLOOR, ST LOUIS, MO, 63102, US

(21) Appl. No.: 10/039,459

(22) Filed: Nov. 7, 2001

Related U.S. Application Data
(60) Provisional application No. 60/258,296, filed on Dec. 26, 2000.

(51) Int. Cl. C30B 15/02; C30B 15/00; C30B 27/02; C30B 21/06; C30B 28/10; C30B 30/04

(52) U.S. Cl. 117/13; 117/19

(57) ABSTRACT

A method and apparatus for producing silicon single crystals with reduced iron contamination is disclosed. The apparatus contains at least one structural component constructed of a graphite substrate and a silicon carbide protective layer covering the surface of the substrate that is exposed to the atmosphere of the growth chamber. The graphite substrate has a concentration of iron no greater than about 1.5*10¹² atoms/cm³and the silicon carbide protective layer has a concentration of iron no greater than about 1.0*10¹² atoms/cm³.

### CROSS-REFERENCE TO RELATED APPLICATIONS

This application claims the benefit of U.S. Provisional Application No. 60/258,296, filed Dec. 26, 2000.

### BACKGROUND OF THE INVENTION

The present invention relates to a process and apparatus for the preparation of single silicon crystals having a reduced level of metallic contamination. More specifically, the present invention relates to a process and apparatus for the preparation of low-iron impurity single silicon crystals wherein structural components in the crystal growth chamber of a Czochralski crystal pulling apparatus have a reduced concentration of iron.

Single crystal silicon which is the starting material for most processes for the fabrication of semiconductor electronic components is commonly prepared with the so-called Czochralski process. In this process, polycrystalline silicon (“polysilicon”) is charged into a crucible, the polysilicon is melted, a seed crystal is immersed into the molten silicon and a single crystal silicon ingot is grown by slow extraction to a desired diameter. After formation of a neck is complete, the diameter of the crystal is enlarged by decreasing the pulling rate and/or the melt temperature until the desired or target diameter is reached. The cylindrical main body of the crystal which has an approximately constant diameter is then grown by controlling the pull rate and the melt temperature while compensating for the decreasing melt level. Near the end of the growth process but before the crucible is emptied of molten silicon, the crystal diameter must be reduced gradually to form an end-cone. Typically, the end-cone is formed by increasing the crystal pull rate and heat supplied to the crucible. When the diameter becomes small enough, the crystal is then separated from the melt.

During the crystal growth process, iron is incorporated in the crystals through the polycrystalline silicon charge, the quartz crucible, and graphite hot zone structural components such as the susceptor, heaters, thermal shields, or insulation which control the heat flow around the crucible and the cooling rate of the growing crystal. The iron impurities in the polycrystalline charge and crucible diffuse throughout the melt and produce iron concentrations which do not vary along the radial direction of the ingot and/or wafer. In contrast, metallic impurities which evaporate out of graphite structural components diffuse into the growing crystal from the periphery. As a result, the concentration of metallic impurities in general, and iron in particular, increases radially outwardly from the central axis to the edge of the crystal. In addition to a radial variation, the concentration of iron within an ingot varies axially. Typically, the iron concentration in the main body of an ingot decreases axially from the seed end to the tail end. The axially variation in iron is due in part to the fact that the earlier grown portions of the ingot are exposed to the evaporated iron for a longer period of time than later grown portions of the ingot.

Heavy metals strongly influence the electrical characteristics of silicon devices. The initial electrical effect is the introduction of energy levels near the center of the bandgap of silicon. These levels may act as recombination centers thus decreasing the minority carrier recombination lifetime, a material parameter which strongly influences electrical characteristics such as leakage current, switching behavior, and storage time in metal oxide semiconductor (MOS) memories. Likewise, the role of the intermediate energy level as a generation center may affect, and thus distort, the ideal current-voltage characteristics of the p-n junction. Metallic impurities frequently cause various types of lattice defects such as metallic precipitates, stacking faults or dislocations that form in the active region on the surface of silicon substrates. These defects on the surface have a fatal influence on device performance and yield. In particular, it is known that iron and molybdenum reduce minority carrier lifetimes in silicon wafers, and copper and nickel can lead to oxygen induced stacking faults in the resulting crystal.

In order to reduce the risk of crystal contamination with contaminants which can be outgassed by graphite parts located around the growing crystal, it is common for graphite components within the hot zone to be coated with a protective barrier layer. Typically, the protective layer is silicon carbide because of its relatively high purity, chemical stability and heat resistance. See, e.g., D. Gilmore, T. Arahori, M. Ito, H. Murakami and S. Miki, “The impact of graphite furnace parts on radial impurity distribution in CZ grown single crystal silicon,” J. Electrochemical Society, Vol. 145, No. 2, (Feb. 1998), pp. 621-628. Silicon carbide coatings provide a barrier to impurity outgassing by sealing the graphite surface, thus requiring impurities to pass through the coating by grain boundary and bulk diffusion mechanisms.

Although graphite substrates coated with a thin layer of silicon carbide have been used to overcome this problem to a certain extent, the introduction of “closed” hot zone configurations and increasingly stringent specifications for metal content in silicon wafers have rendered the existing graphite substrates coated with silicon carbide unsatisfactory. Closed hot zone configurations have been implemented to reduce the density of agglomerated intrinsic point defects (e.g., D-defects, Flow Pattern Defects, Gate Oxide Integrity Defects, Crystal Originated Particle Defects, crystal originated Light Point Defects and interstitial-type dislocation loops) by controlling, among other things, the cooling rate of the growing silicon ingot during critical temperature ranges (e.g., between about the solidification temperature, i.e., about 1300° C., and about 1050° C.). Typically, the cooling rate is controlled, in part, by including structural components such as upper, intermediate and lower heat shields above the melt surface. See, e.g., U.S. Pat. No. 5,942,302. As a comparison, for ingot temperatures from about solidification, about 1300° C., to about a 1000° C., a closed hot zone design typically limits the cooling rate to about 0.8° C./mm to about 1.0° C./mm whereas a conventional open hot zone design cools the ingot at about 1.4° C./mm to about 1.6° C./mm.

In addition to using closed hot zone designs to avoid the formation of agglomerated intrinsic point defects, single crystal silicon ingots are allowed to dwell at a temperature between the temperature of solidification and a temperature of about 1050° C. to about 900° C., and preferably of about 1025° C. to about 925° C., for a period of (i) at least about 5 hours, preferably at least about 10 hours, and more preferably at least about 15 hours for 150 mm nominal diameter silicon crystals, (ii) at least about 5 hours, preferably at least about 10 hours, more preferably at least about 20 hours, still more preferably at least about 25 hours, and most preferably at least about 30 hours for 200 mm nominal diameter silicon crystals, and (iii) at least about 20 hours, preferably at least about 40 hours, more preferably at least about 60 hours, and most preferably at least about 75 hours for silicon crystals having a nominal diameter greater than 200 mm. It is to be noted, however, that the precise time and temperature to which the ingot is cooled is at least in part a function of the concentration of intrinsic point defects, the number of point defects which must be diffused in order to prevent supersaturation and agglomeration from occurring, and the rate at which the given intrinsic point defects diffuse (i.e., the diffusivity of the intrinsic point defects).

Although closed hot zones effectively reduce agglomerated intrinsic point defects (e.g., single crystal silicon grown in an open hot zone design typically has about 1*10³ to about 1*10⁷ defects/cm³, whereas single crystal silicon grown in a closed hot zone typically has less than about 1*10³ defects/cm³), the increased amount of structural graphite, the higher temperatures, the closer proximity of structural components to the growing ingot and melt, and the longer duration of the pulling process can contribute to the increased amount of iron diffusing into the grown crystal. For example, crystals grown in a typical open hot zone usually have an average iron concentration of about 1.0 part per trillion atomic (ppta) and an edge iron concentration of about 1.0 to about 1.5 ppta, whereas crystals grown in a typical closed hot zone usually have an average iron concentration of about 5 to about 10 ppta and an edge iron concentration as high as 100 ppta.

U.S. Pat. No. 5,919,302, along with PCT/US98/07305, PCT/US/07365, and PCT/US99/14285 provide further details for growing single crystal silicon which is substantially free of agglomerated defects. All matter disclosed in the foregoing patent and applications is hereby incorporated herein for all purposes.

Therefore, a need exists in the semiconductor industry for a method which will further reduce the level of metallic contaminants entering the silicon crystal during the growing process due to particulate generated from structural components within the hot zone of the crystal pulling apparatus.

### BRIEF SUMMARY OF THE INVENTION

Generally, the present invention is directed to a crystal pulling apparatus for producing a silicon single crystal grown by the Czochralski process. More specifically, the apparatus comprises a growth chamber and a structural component disposed within the growth chamber. The structural component comprises a substrate and a protective layer covering the surface of the substrate that is exposed to the atmosphere of the growth chamber. The substrate comprises graphite and has a concentration of iron no greater than about 1.5*10¹² atoms/cm³ and the protective layer comprises silicon carbide and has a concentration of iron no greater than about 1.0*10¹² atoms/cm³.

The present invention is further directed to a process for controlling the contamination of a silicon single crystal with iron during the growth of the silicon crystal. The process comprises pulling the silicon single crystal from a pool of molten silicon within a growth chamber of a crystal pulling apparatus constructed with a structural component comprising a substrate and a protective layer covering the surface of the substrate that is exposed to the atmosphere of the growth chamber. The substrate comprises graphite and has a concentration of iron no greater than about 1.5*10¹² atoms/cm³. The protective layer comprises silicon carbide and has a concentration of iron no greater than about 1.0*10¹² atoms/cm³.

Other objects and features of the present invention will be in part apparent and in part pointed out hereinafter.

### BRIEF DESCRIPTION OF THE SEVERAL VIEWS OF THE DRAWING

FIG. 1 is a diagram of a silicon single crystal pulling apparatus.

FIG. 2 is a diagram of an apparatus used to diffuse iron from graphite and silicon carbide coated graphite samples into a silicon wafer in order to determine the iron concentration in the samples.

FIG. 3 is a graph which shows the concentrations of iron in four different graphite samples when uncoated and coated with two different silicon carbide layers.

FIG. 4 is a graph which shows the average edge iron concentration as a function of axial position for three ingots pulled under three conditions, a hot zone constructed with conventional structural components, the same hot zone with an extra 50 liters/min argon purge gas, and a hot zone constructed with low impurity structural components.

### DETAILED DESCRIPTION OF THE INVENTION

In accordance with the present invention, it has been discovered that by pulling a silicon single crystal within a crystal pulling apparatus comprising a growth chamber, a closed hot zone and high purity structural components, the concentration of iron impurities in the grown crystal is significantly reduced.

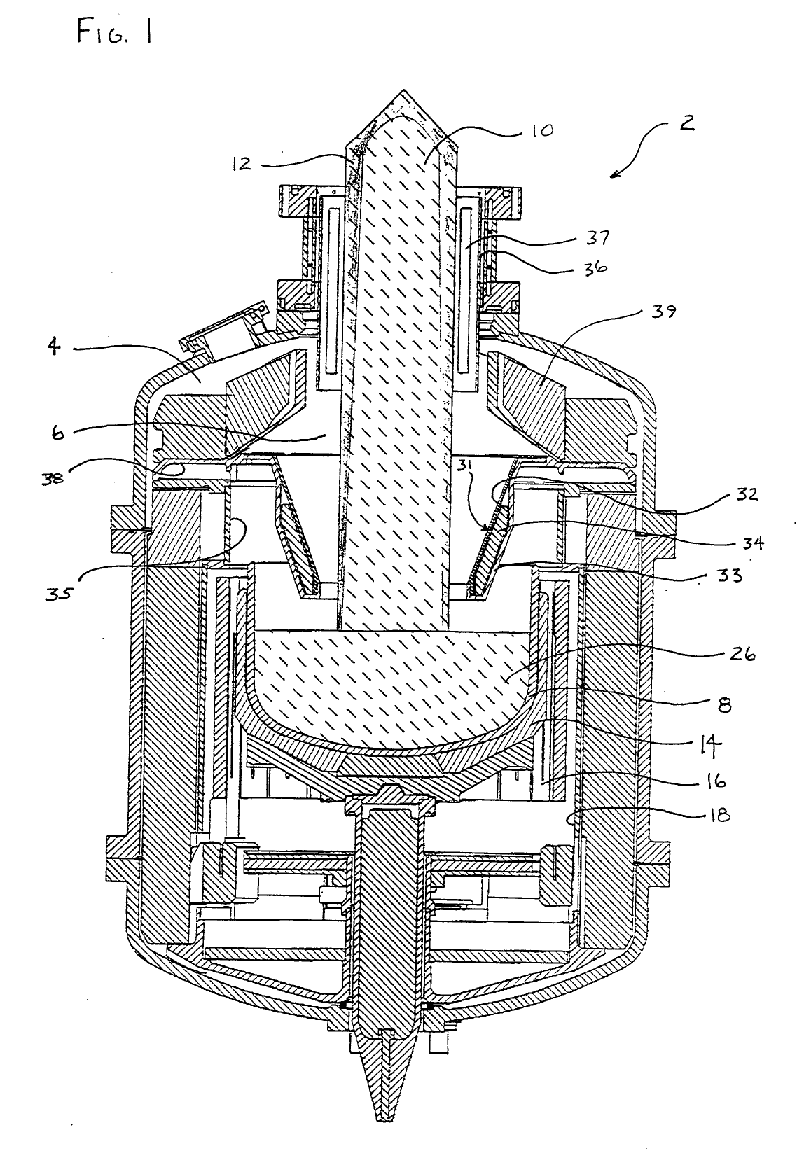

Referring now to FIG. 1, there is shown a crystal pulling apparatus indicated generally at 2. The apparatus comprises a crystal growth chamber 4 and a crystal chamber 6. Contained within crystal growth chamber 4 is a silica crucible 8 which contains molten polysilicon 26 for growing the silicon single crystal. A pulling wire (not shown) attached to a wire rotation device (not shown) is used to slowly extract the growing crystal during operation. Also contained within the crystal growth chamber 4 are several structural components which surround the crucible such as a susceptor 14 for holding the crucible in place, a melt heater 16 for heating the silicon melt, and a melt heater shield 18 for retaining heat near the crucible. A growth chamber with a closed hot zone design may also contain structural components such as a lower heat shield 31 that comprises an inner reflector 32, an outer reflector 33 and an insulation layer 34 sandwiched between coaxially positioned inner and outer reflectors 32 and 33, respectively. A closed hot zone design may also comprise an intermediate heat shield 35, and an upper heater shield 36. As previously stated, these structural components are typically constructed of graphite and control the heat flow around the crucible and the rate of cooling of the silicon single crystal. It should be recognized by one skilled in the art that other structural components such as the upper heater 37, upper insulation support 38, or upper insulation shield 39 may also be prepared for use in accordance with the present invention.

FIG. 1 also depicts the iron contamination in the growing single crystal ingot 10 with iron emanating from structural components within the growth chamber (e.g., lower heat shield 31, intermediate heat shield 35, and upper heater shield 36). The portion of ingot 10 which is shaded 12 (not to scale), represents “edge” iron contamination of a silicon ingot grown in a closed hot zone constructed with conventional structural components. Edge iron is the common designation for iron contamination around the circumference of an ingot/wafer. Typically the extent of edge iron contamination is referred to as “edge iron concentration” which is the average iron concentration for the annular portion of a silicon wafer or main body of an ingot extending radially inward about 5 millimeters from the circumferential edge. The extent of edge iron contamination also affects the “average iron concentration” which is the average concentration of iron throughout an entire silicon wafer or main body of an ingot.

In accordance with the present invention, structural components utilized in a growth chamber comprise a substrate and a protective layer. The substrate of the present invention comprises graphite, preferably the substrate is at least about 99.9% pure graphite, and more preferably at least about 99.99% or more pure graphite. Further, the graphite preferably contains less than about 3 ppmw total metals such as iron, molybdenum, copper and nickel, and more preferably less than about 1.5 ppmw. The concentration of iron in conventional hot zone graphite ranges from about 2.8*10¹⁶ atoms/cm³ (1.0 ppmw) to about 1.4*10¹⁵ atoms/cm³ (0.05 ppmw). However, the concentration of iron in a substrate used in accordance with the present invention is no more than about 1.5*10¹² atoms/cm³, preferably no more than about 1.0*10¹² atoms/cm³, more preferably no more than about 0.5*10¹² atoms/cm³, and still more preferably no more than about 0.1*10¹² atoms/cm³.

The protective layer covering at least the surface of the substrate which is exposed to the atmosphere of the growth chamber comprises silicon carbide, preferably the protective layer comprises between about 99.9% to about 99.99% silicon carbide. Preferably, the entire surface of the substrate is covered with the protective layer. Preferably, the silicon carbide protective coating contains less than about 2 ppmw total metals such as iron, molybdenum, copper and nickel, and more preferably less than about 1.5 ppmw. The concentration of iron in conventional hot zone silicon carbide coatings ranges from about 0.8 to about 0.5 ppmw. In contrast, the concentration of iron in the protective coating used in accordance with the present invention is no more than about 1.0*10¹² atoms/cm³, preferably no more than about 0.5*10¹² atoms/cm³ of iron, and more preferably no more than about 0.1*10¹² atoms/cm³ of iron. The thickness of the protective coating is generally at least about 75 micrometers, preferably between about 75 and about 125 micrometers, and more preferably about 100 micrometers.

According to the process of the present invention, the average iron concentration and the edge iron concentration in a single crystal silicon ingot grown in a closed hot zone is reduced by replacing at least one conventional hot zone component with at least one low-iron impurity component constructed in view of the foregoing (e.g., upper heater, upper heater shield intermediate heat shield, the inner reflector, the outer reflector and the insulation layer of the lower heat shield, intermediate heat shield, upper insulation support, and upper insulation shield). More specifically, the iron concentration (average and edge) in the single crystal silicon is reduced by using at least one low-iron impurity structural component in a location in which the component will reach at least about 950° C. for at least about 80 hours of the growth process and is within about 3 cm to about 5 cm from silicon melt or the ingot. It has been observed that the average and edge iron concentrations decrease with increasing numbers of such low-iron structural components within the growth chamber. Thus, preferably more than one conventional hot zone component is replaced with a low-iron component. For example, it has been observed that silicon ingots/wafers having an edge iron concentration below about 5 ppta and an average iron concentration below about 3 ppta are produced by replacing at least the following six conventional components with low iron impurity components during the ingot growth process: the upper heater, the upper heater shield, the intermediate heat shield, and the inner reflector, the outer reflector and the insulation layer of the lower heat shield. Preferably, the edge iron concentration is below about 3 ppta and the average iron concentration is below about 2 ppta, and more preferably the edge iron concentration is below about 1 ppta and the average iron concentration is below about 0.8 ppta. Preferably, two additional components are replaced: the upper insulation support, and the upper insulation shield. More preferably, all structural components which reach at least about 950° C. for at least about 80 hours of the growth process and are within about 3 cm to about 5 cm from the silicon melt or growing ingot are replaced with low-iron impurity structural components.

Definitions

As used herein, the following phrases or terms shall have the given meanings: “agglomerated intrinsic point defects” mean defects caused (i) by the reaction in which vacancies agglomerate to produce D-defects, flow pattern defects, gate oxide integrity defects, crystal originated particle defects, crystal originated light point defects, and other such vacancy related defects, or (ii) by the reaction in which self-interstitials agglomerate to produce dislocation loops and networks, and other such self-interstitial related defects; “agglomerated interstitial defects” shall mean agglomerated intrinsic point defects caused by the reaction in which silicon self-interstitial atoms agglomerate; “agglomerated vacancy defects” shall mean agglomerated vacancy point defects caused by the reaction in which crystal lattice vacancies agglomerate; “substantially free of agglomerated intrinsic point defects” shall mean a concentration of agglomerated defects which is less than the detection limit of these defects, which is currently about 10³ defects/cm³; “radius” means the distance measured from a central axis to a circumferential edge of a wafer or ingot.

The present invention is further illustrated by the following examples which are merely for the purpose of illustration and are not to be regarded as limiting the scope of the invention or manner in which it may be practiced.

### EXAMPLE 1

### Determining an Acceptable Concentration of Iron Impurity in Closed Hot Zone Structural Components

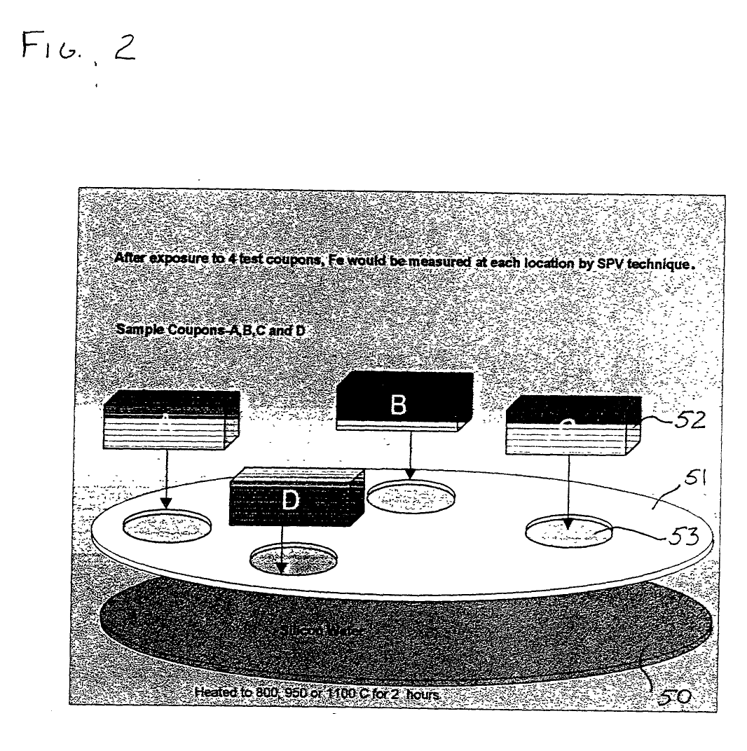

A horizontal furnace tube was used to expose a monitor wafer via gas diffusion to four samples: 1) a standard graphite sample without any protective coating; 2) the standard graphite coated with silicon carbide from supplier A; 3) the standard graphite coated with silicon carbide from supplier B; and 4) the standard graphite coated with silicon carbide from supplier C. The samples were coupons about 50 mm×50 mm×2 5mm in size. A fused silica mask was utilized to separate the monitor wafer from each test sample. Four holes in the mask allowed the monitor wafer to be exposed to gases generated from the sample materials. Referring to FIG. 2, each test stack consisted of a monitor wafer 50 for measuring the amount of iron transferred via diffusion, a fused silica mask 51 on top of the monitor wafer, and a sample 52 on top of a hole 53 in the mask. For each run, one wafer was used as a background sample and did not have a mask or samples on it.

Each of the samples were tested to measure iron diffusivity to the monitor wafer at three different temperatures: 800° C., 950° C. and 1100° C. The samples were held at atmospheric pressure throughout the two hour heat treatment, and a stream of argon gas over the wafers was maintained.

After each heat treatment, the wafer was sliced into quarter sections; each section containing the iron diffused from each sample. The minority carrier lifetime was determined for each wafer section and the background wafer. The minority carrier lifetime was used to determine the amount of iron present in the silicon wafer using the surface photovoltaic technique developed by G. Zoth and W. Bergholz described in the Journal of Applied Physics, vol. 67, (1990), pp. 6764-6771. The minority carrier lifetime was measured by injecting carriers into the silicon wafer sample by means of light and observing their decay by monitoring the change in the surface photovoltage effect. The surface photovoltage technique is the most sensitive method of measuring carrier diffusion length and is an accurate method for the quantitative evaluation of iron in silicon wafers. The method is based on the fact that, in silicon, iron atoms react with negatively charged boron acceptor atoms to form Fe—B pairs. Typically, the Fe—B pairs are generated by annealing the samples at about 70° C. for about 30 minutes. When heated, a portion of the Fe—B pairs disassociate and generate interstitial iron (Feᵢ) defects. All the Fe—B pairs disassociate, however, with illumination using a 250-Watt tungsten-halogen lamp. See, e.g., J. Lagowski, P. Edelman, 0. Millic, W. Henly, M. Dexter, J. Jastrezebski and A. M. Hoff, Applied Physics Letters, vol. 63, (1993), pp. 3043-3045. The concentration of iron in silicon is determined by comparing the minority carrier lifetime values at the two states set forth in the following equation:

[Fe]=(0.7/A)×(10¹⁶)×(1/L²−1/L₀²) (1).

L₁ and L₀ are minority carrier diffusion lengths in microns before and after the dissociation of Fe—B pairs, respectively, and A is the fraction of Fe—B pairs dissociated during thermal activation.

TABLE 1
Iron Evolved from a Structural Component
as a Function of Temperature

| | Temperature | | |
|---|---|---|---|
| Structural | 800° C. | 950° C. | 1100° C. |
| Component | (atoms/cc) | (atoms/cc) | (atoms/cc) |
| Uncoated | 1.24*10¹² | 1.35*10¹³ | 1.51*10¹⁴ |
| Graphite | | | |
| SiC coated | 9.37*10¹¹ | 3.52*10¹³ | 7.45*10¹⁴ |
| graphite - | | | |
| Supplier A | | | |
| SiC coated | 1.18*10¹¹ | 9.87*10¹² | 8.98*10¹³ |
| graphite - | | | |
| Supplier B | | | |
| SiC coated | 9.71*10¹² | 9.71*10¹³ | 9.37*10¹³ |
| graphite - | | | |
| Supplier C | | | |

The results in listed Table 1 indicate that the amount of iron evolved from a structural component increases with increasing temperature. At present, the maximum temperature that can be reached by this method is 1100° C.; during a typical closed hot zone growth process structural components can reach about 1250° C. for about 80 hours. Results to date, however, indicate that most of the iron present in the sample coupons come out in the form of vapor at 1100° C. Thus, testing a sample at 1100° C. in accordance with the foregoing procedures provides an accurate measurement of the total concentration of iron impurity within the sample.

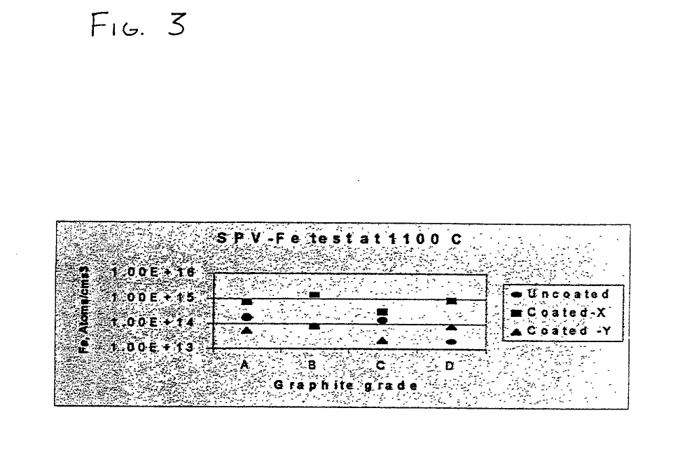

Using the foregoing procedures, the concentration of iron in the graphite of four suppliers was determined without a silicon carbide coating and with two different coatings. The results of the test, depicted in FIG. 3, clearly indicate that there is significant variability in the concentration of iron in the graphite from the suppliers that were tested. Also, the results indicate that in some cases adding a coating may substantially increase the amount of iron evolved (see, graphite B, coating X and graphite D, coating X). On the other hand, the coating may decrease the amount of iron evolved (see, graphite A, coating Y; graphite C, coating Y; and graphite D, coating Y). The results clearly indicate that the silicon carbide coating designated X has a higher iron concentration than the Y coating. Thus, in contrast to Gilmore et al. at p. 626, to effectively control the amount of iron contamination in single crystal silicon grown in a growth chamber having a closed hot zone the concentration of iron in the graphite and the silicon carbide coating must be controlled.

### EXAMPLE 2

### Pulling Single Crystal Silicon in a Growth Chamber Containing Reduced Iron Impurity Structural Components

The concentration of iron impurity in single crystal silicon ingots grown in a Czochralski crystal puller having a closed hot zone design constructed with conventional structural components was compared to that achieved using low-iron structural components. Specifically, three ingots were pulled under three conditions, a hot zone constructed with conventional structural components, the same hot zone with an extra 50 liters/min argon purge gas, and a hot zone constructed with low impurity structural components. The low iron impurity structural components used in the growth chamber were the upper heater, the upper heater shield, the intermediate heat shield, the inner reflector, the outer reflector and the insulation layer of the lower heat shield, the upper insulation support, and the upper insulation shield. The concentration of iron in the carbon substrates was about 0.5×10¹² atoms/cm³. The concentration of iron in the silicon carbide protective layer was about 0.1×10¹² atoms/cm³.

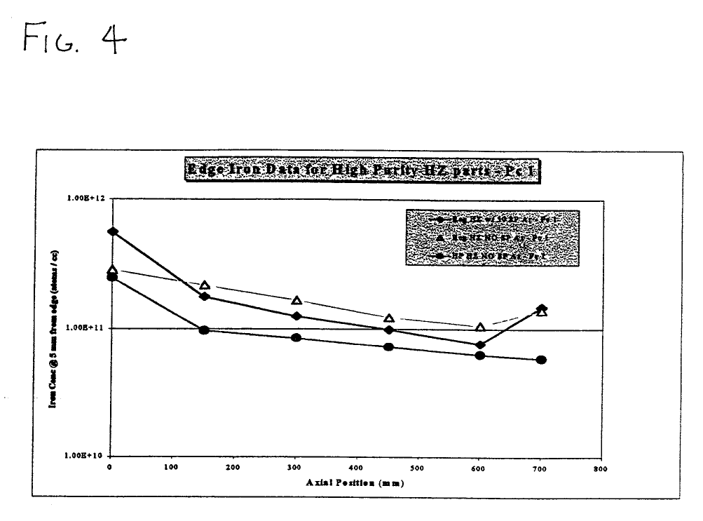

FIG. 4 compares the average edge iron of three crystals produced using standard and high purity hot zone parts as a function of axial position. FIG. 4 clearly shows that growing silicon crystal grown in chambers constructed with low iron impurity hot zone parts decreases the edge iron concentration. In fact, the average edge iron concentration in these crystals was about 50% lower than that of crystals produced using conventional hot zone parts.

In view of the above, it will be seen that the several objects of the invention are achieved and other advantageous results attained. It is intended that all matter contained in the above description shall be interpreted as illustrative and not in a limiting sense.

What is claimed is:

1. A crystal pulling apparatus for producing a silicon single crystal grown by the Czochralski process, the apparatus comprising:
a growth chamber; and
a structural component disposed within the growth chamber, the structural component comprising a substrate and a protective layer covering the surface of the substrate that is exposed to the atmosphere of the growth chamber, the substrate comprising graphite and having a concentration of iron no greater than about 1.5*10¹² atoms/cm³, the protective layer comprising silicon carbide and having a concentration of iron no greater than about 1.0*10¹² atoms/cm³.

2. The crystal pulling apparatus as set forth in claim 1 wherein the concentration of iron in the substrate is no greater than about 1.0*10¹² atoms/cm³.

3. The crystal pulling apparatus as set forth in claim 1 wherein the concentration of iron in the substrate is no greater than about 0.5*10¹² atoms/cm³.

4. The crystal pulling apparatus as set forth in claim 1 wherein the concentration of iron in the substrate is no greater than about 0.1*10¹² atoms/cm.

5. The crystal pulling apparatus as set forth in claim 1 wherein the concentration of iron in the protective layer is no greater than about 0.5*10¹² atoms/cm³.

6. The crystal pulling apparatus as set forth in claim 1 wherein the concentration of iron in the protective layer is no greater than about 0.1*10¹² atoms/cm³ of iron.

7. The crystal pulling apparatus as set forth in claim 1 wherein the protective layer is about 75 to about 125 μm thick.

8. The crystal pulling apparatus as set forth in claim 1 wherein the protective layer is about 100 μm thick.

9. The crystal pulling apparatus as set forth in claim 1 wherein the protective layer covers the entire surface of the substrate.

10. The crystal pulling apparatus as set forth in claim 1 wherein the structural component reaches at least about 950° C. for at least about 80 hours and is within about 3 cm to about 5 cm of the silicon single crystal or a silicon melt during the growth of the silicon single crystal.

11. The crystal pulling apparatus as set forth in claim 10 wherein the structural component is selected from the group consisting essentially of an upper heater, an upper heater shield, an intermediate heat shield, a lower heat shield inner reflector, a lower heat shield outer reflector, a lower heat shield insulation layer, an upper insulation support and an upper insulation shield.

12. The crystal pulling apparatus as set forth in claim 11 comprising at least six structural components selected from the group.

13. The crystal pulling apparatus as set forth in claim 11 comprising at least eight structural components selected from the group.

14. The crystal pulling apparatus as set forth in claim 1 wherein all the structural components which during the growth of the crystal reach at least about 950° C. for at least 80 hours and are within about 3 cm to about 5 cm of the crystal or a silicon melt comprise the substrate and the protective layer.

15. A process for controlling the contamination of a silicon single crystal ingot with iron from a structural component in a crystal growing apparatus during the growth of the silicon single crystal ingot, the process comprising:
constructing the crystal growing apparatus with a growth chamber and a structural component disposed within the growth chamber, the structural component comprising a substrate and a protective layer covering the surface of the substrate that is exposed to the atmosphere of the growth chamber, the substrate comprising graphite and having a concentration of iron no greater than about 1.5*10¹² atoms/cm³, the protective layer comprising silicon carbide and having a concentration of iron no greater than about 1.0*10¹² atoms/cm³; and
pulling the silicon single crystal ingot from a pool of molten silicon within the growth chamber.

16. The process as set forth in claim 15 wherein the concentration of iron in the substrate is no greater than about atoms 1.0*10¹² atoms/cm³.

17. The process as set forth in claim 15 wherein the concentration of iron in the substrate is no greater than about 0.5*10¹² atoms/cm³.

18. The process as set forth in claim 15 wherein the concentration of iron in the substrate is no greater than about 0.1*10¹² atoms/cm.

19. The process as set forth in claim 15 wherein the concentration of iron in the protective layer is no greater than about 0.5*10¹² atoms/cm³.

20. The process as set forth in claim 15 wherein the concentration of iron in the protective layer is no greater than about 0.1*10¹² atoms/cm³ of iron.

21. The process as set forth in claim 15 wherein the protective layer is about 75 to about 125 μm thick.

22. The process as set forth in claim 15 wherein the protective layer is about 100 μm thick.

23. The process as set forth in claim 15 wherein the protective layer covers the entire surface of the substrate.

24. The process as set forth in claim 15 wherein the structural component reaches at least about 950° C. for at least about 80 hours and is within about 3 cm to about 5 cm of the silicon single crystal or the pool of molten silicon during the growth of the silicon single crystal.

25. The process as set forth in claim 24 wherein the structural component is selected from the group consisting essentially of an upper heater, an upper heater shield, an intermediate heat shield, a lower heat shield inner reflector, a lower heat shield outer reflector, a lower heat shield insulation layer, an upper insulation support and an upper insulation shield.

26. The process as set forth in claim 25 comprising constructing the crystal growing apparatus with at least six structural components selected from the group.

27. The process as set forth in claim 25 comprising constructing the crystal growing apparatus with at least eight structural components selected from the group.

28. The process as set forth in claim 15 comprising constructing the crystal growing apparatus such that all the structural components which during the growth of the crystal reach at least about 950° C. for at least 80 hours and are within about 3 cm to about 5 cm of the crystal or a silicon melt comprise the substrate and the protective layer.

29. The process as set forth in claim 15 wherein the silicon single crystal ingot comprises a main body that has an edge iron concentration less than that of a reference silicon single crystal ingot pulled in a reference growth chamber operated under identical conditions and constructed of identical components except having a reference structural component with a concentration of iron greater than about 1.4*10¹⁵ atoms/cm³.

30. The process as set forth in claim 26 wherein the silicon single crystal ingot comprises a main body that has an edge iron concentration below about 5 ppta.

31. The process as set forth in claim 26 wherein the silicon single crystal ingot comprises a main body that has an edge iron concentration below about 3 ppta.

32. The process as set forth in claim 27 wherein the silicon single crystal ingot comprises a main body that has an edge iron concentration below about 1 ppta.

33. The process as set forth in claim 28 wherein the silicon single crystal ingot comprises a main body that has an edge iron concentration below about 1 ppta.
